(19) United States
(12) Patent Application Publication
(10) Pub. No.: US 2010/0221412 A1
(43) Pub. Date: Sep. 2, 2010

(54) METHOD FOR MANUFACTURING A SUBSTRATE

(75) Inventor: CHING-YAO FU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/577,827

(22) Filed: Oct. 13, 2009

(30) Foreign Application Priority Data
Feb. 27, 2009 (TW) 98106506

(51) Int. Cl. H05K 3/00

(52) U.S. Cl. 427/97.4

(57) ABSTRACT

In a method for manufacturing a substrate, copper is applied to one surface of the substrate to form a plurality of circuit traces, defining one or more copper clearance areas therebetween. Dry film is coated on one portion of the circuit traces and the one or more copper clearance areas, and another portion of the plurality of copper traces remains uncoated. The dry film on the substrate is flattened to form a dry film layer. The other portion of the plurality of circuit traces is plated to form a plating layer. A surface of the plating layer is substantially coplanar with a surface of the dry film layer.

### BACKGROUND

1. Technical Field

Embodiments of the present disclosure relate to substrate manufacturing, and especially to a method for manufacturing a substrate having a substantially even surface.

2. Description of Related Art

FIG. 2 is a schematic diagram of a commonly manufactured substrate 10. At least one electronic component 11 is disposed on a first surface of the substrate 10. A second surface of the substrate 10 opposite to the first surface receives circuit traces. During manufacture of the second surface of the substrate 10, copper is coated on the second surface of the substrate 10, and a plurality of circuit traces 12 are designed on the copper layer. Liquid solder mask 14 is coated on part of and around the circuit traces 12, providing protection thereof and exposing other parts of the circuit traces 12. The bare circuit traces 12 are plated. However, the method described can result in a surface that is uneven due to unstable distribution of liquid solder mask 14. Accordingly, the substrate 10 is easily deformed during a subsequent process, and solder between the electronic components 11 and the substrate 10 may be easily cracked.

Therefore, a need exists in the industry to overcome the described limitations.

### BRIEF DESCRIPTION OF THE DRAWINGS

FIG. 1A is a schematic diagram of a substrate manufactured by a method for manufacturing a substrate according to the present disclosure, after applying copper on one surface of the substrate.

FIG. 1B is a schematic diagram of a substrate manufactured by a method for manufacturing a substrate according to the present disclosure, after coating and flattening dry films thereon.

FIG. 1C is a schematic diagram of a substrate manufactured by a method for manufacturing a substrate according to the present disclosure, after plating.

FIG. 2 is a schematic diagram of a commonly manufactured substrate.

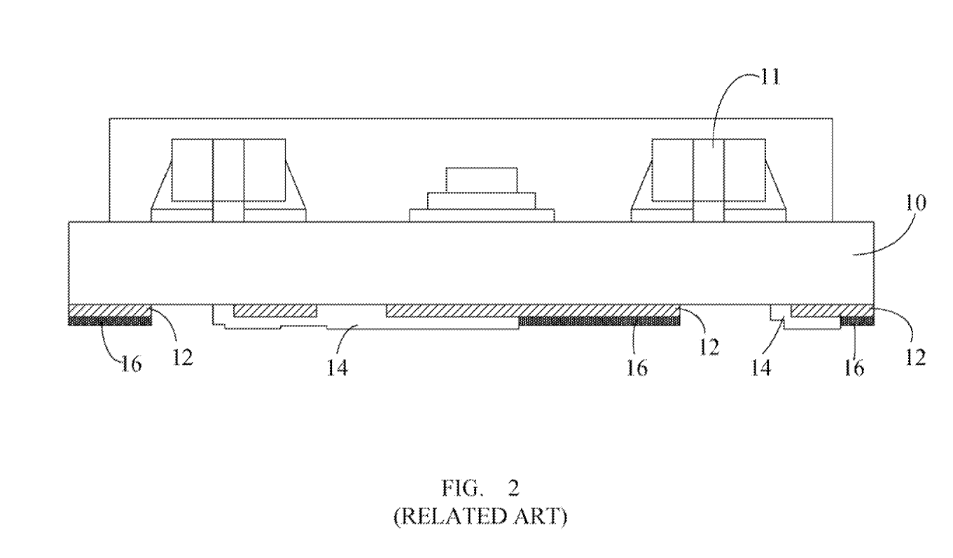

### DETAILED DESCRIPTION

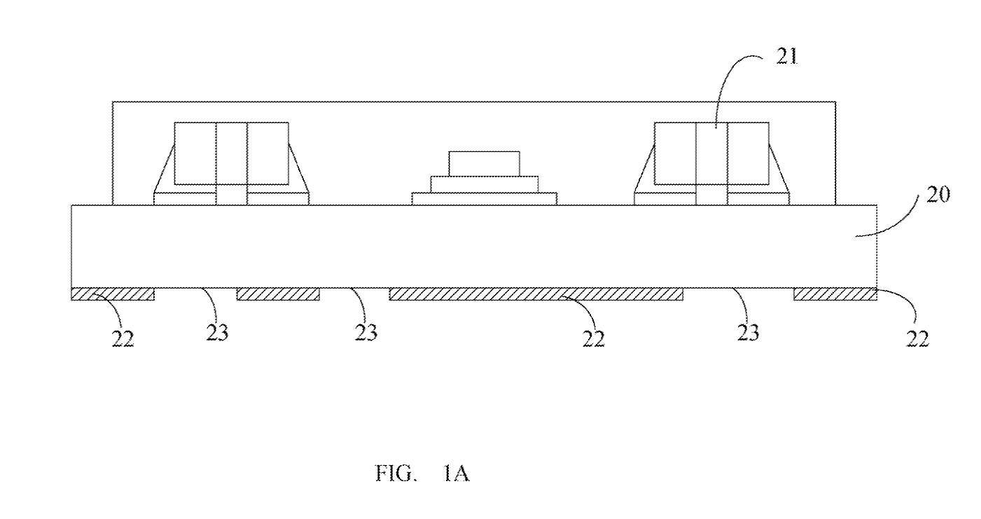

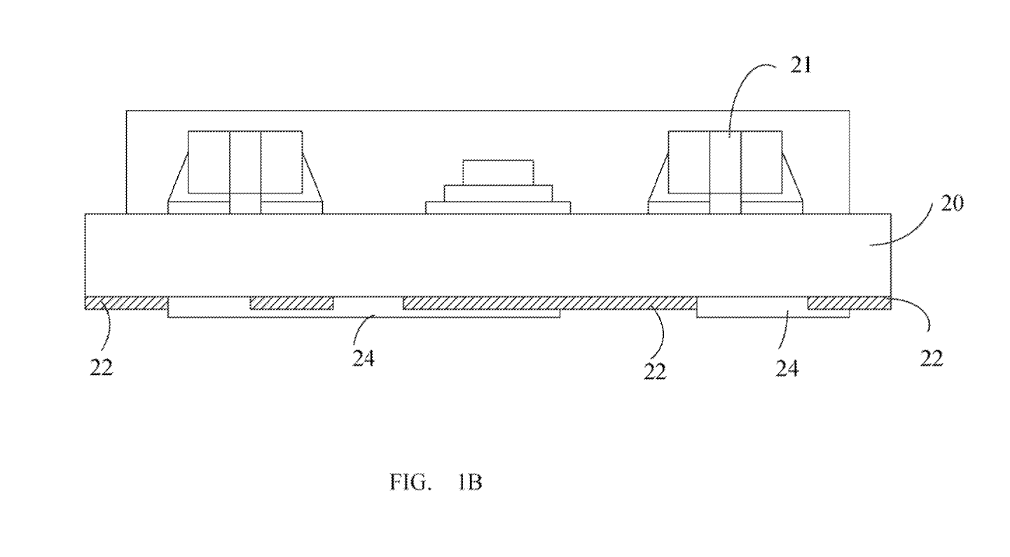

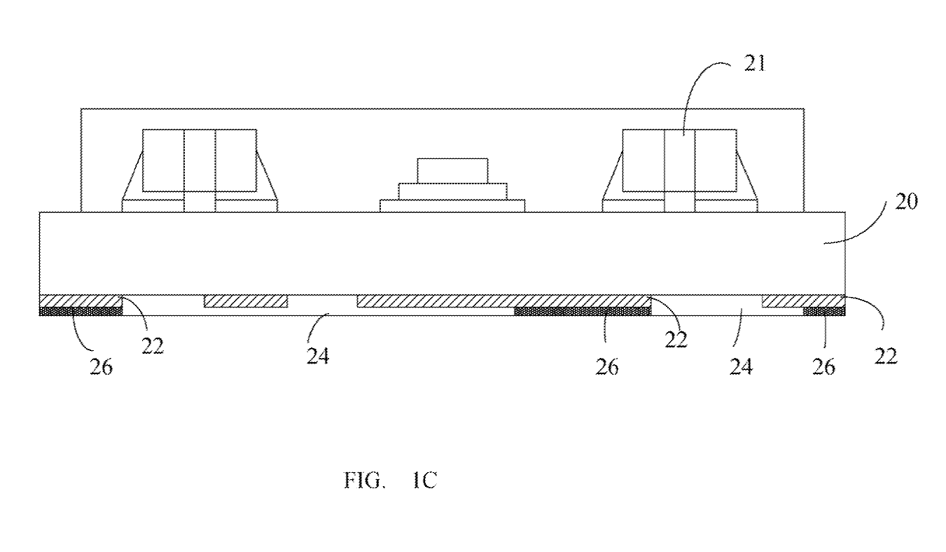

Referring FIG. 1A-FIG. 1C, in a method for manufacturing a substrate according to the present disclosure, at least one electronic component 21 is soldered or surface mounted on a first surface of a substrate 20. A second surface of the substrate 20, opposite to the first surface, receives circuit traces to electrically connect the at least one electronic component 21. In one embodiment, the substrate 20 may be an organic substrate used in an exemplary Land Grid Array (LGA) module.

A method for manufacturing the substrate 20 to obtain a substantially even surface of the substrate, such as the second surface, according to the present disclosure, follows.

Referring to FIG. 1A, the second surface of the substrate 20 is coated with copper to form a plurality of copper traces 22. The plurality of copper traces 22 define one or more copper clearance areas 23 therebetween on the second surface.

Referring to FIG. 1B, one portion of the plurality of copper traces 22 and the copper clearance areas 23 are coated with dry film 24, and the other portion of the plurality of copper traces 22 remain uncoated.

The dry film on the substrate 20 is flattened to form a dry film layer 24. The dry film layer 24 has an even surface, as shown in FIG. 1B.

Finally, referring to FIG. 1C, the other partial portion of the copper traces 22 are plated with a inductive material to form a plating layer 26. In one embodiment, the material may be gold and/or nickel.

In the manufacturing process, a surface of the plating layer 26 is secured to be substantially coplanar with a surface of the dry film layer 24 so as to obtain a substantially even surface. The substrate 20 manufactured via the method disclosed has an even second surface, and is thus able to maintain its shape during manufacture and solder between the electronic component 21, and is not easily cracked.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A method for manufacturing a substrate to obtain an even surface thereof, the method comprising:
applying copper to one surface of the substrate to form a plurality of copper traces, wherein the plurality of cooper traces defines one or more copper clearance areas therebetween;
coating dry film on one portion of the plurality of copper traces and the one or more copper clearance areas, wherein another portion of the plurality of copper traces remain uncoated;
flattening the dry films to form a dry film layer; and
plating the other portion of the plurality of copper traces to form a plating layer;

2. The method for manufacturing a substrate as claimed in claim 1, wherein gold and/or nickel is during plated on the other partial portion of the plurality of copper traces.

3. The method for manufacturing a substrate as claimed in claim 1, wherein the substrate comprises at least one electronic component on a first surface thereof, and the plurality of copper traces are designed on a second surface opposite to the first surface of the substrate.
